(19) United States
(12) Patent Application Publication
(10) Pub. No.: US 2007/0141741 A1
(43) Pub. Date: Jun. 21, 2007

(54) Semiconductor laminated structure and method of manufacturing nitirde semiconductor crystal substrate and nitirde semiconductor device

(75) Inventors: Hyo Won Suh, Soonchun (KR); Masayoshi Koike, Suwon (KR); Sung Hwan Jang, Yongin (KR); Soo Min Lee, Seoul (KR); Jong In Yang, Yongin (KR); Jin Young Hong, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/505,406

(22) Filed: Aug. 17, 2006

(30) Foreign Application Priority Data
Aug. 18, 2005 (KR) 10-2005-0075912

(51) Int. Cl. C30B 21/04; H01L 21/00; H01L 21/336

(52) U.S. Cl. 438/44; 438/269; 117/43

(57) ABSTRACT

In a semiconductor laminated structure, a base substrate has a nitride semiconductor crystal plane in an upper surface thereof. A growth blocking film encloses a flow-through pattern which is extended horizontally on the base substrate at a predetermined interval. A nitride semiconductor crystal layer is formed on the base substrate to contact the upper surface thereof between regions of the flow-through pattern and covers the grow blocking film. The semiconductor laminated structure is employed to obtain a nitride semiconductor crystal layer, nitride semiconductor crystal substrate and nitride semiconductor device exhibiting fewer defects and high quality.

### RELATED APPLICATION

This application claims the benefit of Korean Patent Application No. 2005-0075912 filed on Aug. 18, 2005 in the Korean Intellectual Property Office, the disclosure of which is incorporated herein by reference.

### BACKGROUND OF THE INVENTION

1. Field of the Invention

The present invention relates to a nitride semiconductor crystal substrate and a nitride semiconductor device. More particularly, the present invention relates to a method for manufacturing a high-quality nitride semiconductor substrate and device with fewer crystal defects, and a semiconductor laminated structure used therefor.

2. Description of the Related Art

A group III nitride semiconductor (hereinafter referred to as “a nitride semiconductor”) has a composition expressed by AlₓGa_{y}In_{(1-x-y)}N, where 0≦x≦1, 0≦y≦1, and 0≦x+y≦1. The nitride semiconductor has been highlighted as a material which can be suitably applied to an optoelectric device or a high-capacity field effect device. A traffic light employing a blue light emitting diode based on the nitride semiconductor is in common use. Also, there is a burgeoning demand for a nitride-based LED in areas such as white lighting and displays. Here, a substrate for growing a nitride-based single crystal needs to match with the nitride-based single crystal in terms of lattice constant and thermal coefficient constant. However such a substrate is not yet commercially available.

Typically, a nitride semiconductor layer is grown on a heterogeneous substrate such as a sapphire substrate, a SiC substrate, a GaAs substrate or a Si substrate due to technical difficulty of its formation on the nitride semiconductor substrate. Accordingly, the heterogeneous substrate and nitride semiconductor layer differ in crystal constant and thermal expansion coefficient. This leads to considerable crystal defects such as dislocation in the nitride semiconductor layer grown on the heterogeneous substrate and the nitride semiconductor device formed thereon. The defects are mainly blamed for degrading capability of the nitride semiconductor device such as a light emitting diode (LED).

To overcome such problems, conventionally, the nitride semiconductor layer grown on the heterogeneous substrate has been separated therefrom. For example, U.S Pat. No. 6,071,795 discloses a technology of separating a GaN layer or a GaN-based LED from a sapphire substrate via laser lift off (LLO). But even the aforesaid laser lift off warps the substrate or impairs the semiconductor layer due to differences in thermal expansion coefficient between the sapphire substrate and the nitride semiconductor. Therefore, there is still a strong demand for a highly reliable method for separating a substrate or producing a high-quality nitride semiconductor substrate or nitride semiconductor device.

### SUMMARY OF THE INVENTION

The present invention has been made to solve the foregoing problems of the prior art and therefore an object according to certain embodiments of the present invention is to provide a semiconductor laminated structure which produces a nitride semiconductor substrate or device improved in crystal quality.

Another object according to certain embodiments of the invention is to provide a highly reliable method for manufacturing a high-quality nitride semiconductor crystal substrate using the semiconductor laminated structure.

Further another object according to certain embodiments of the invention is to provide a highly reliable method for manufacturing a high-quality nitride semiconductor device using the semiconductor laminated structure.

According to an aspect of the invention for realizing the object, there is provided a semiconductor laminated structure including a base substrate having a nitride semiconductor crystal plane in an upper surface thereof; a growth blocking film enclosing a flow-through pattern which is extended horizontally on the base substrate at a predetermined interval; and a nitride semiconductor crystal layer formed on the base substrate to contact the upper surface thereof between regions of the flow-through pattern, the nitride semiconductor crystal layer covering the growth blocking film. This semiconductor laminated structure is easily applicable in producing a nitride semiconductor crystal layer, substrate and device exhibiting fewer defects and high quality.

According to an embodiment of the invention, the base substrate is a nitride semiconductor substrate. According to another embodiment, the base substrate comprises a heterogeneous substrate in a lower part and a nitride semiconductor layer in an upper part.

Preferably, the growth blocking film comprises one selected from a group consisting of SiO₂, SiNₓ and Al₂O₃. Alternatively, the growth blocking film comprises a refractory metal.

According to another aspect of the invention for realizing the object, there is provided a method for manufacturing a nitride semiconductor crystal substrate comprising steps of:

forming a pattern of a thermally-decomposable material and a growth blocking film enclosing the pattern on a base substrate having a nitride semiconductor crystal plane in an upper surface thereof;

etching the growth blocking film between regions of the pattern to expose partial areas of the crystal plane of the base substrate;

forming a nitride semiconductor crystal layer covering the growth blocking film by growing a nitride semiconductor crystal from the partial areas of the exposed crystal plane while the thermally-decomposable material is thermally decomposed to form a flow-through pattern; and

flowing an etchant through the flow-through pattern to separate the nitride semiconductor crystal layer from the base substrate.

According to an embodiment of the invention, the step of forming the pattern of the thermally-decomposable material and the growth blocking film comprises: forming a first growth blocking film on the base substrate; forming the pattern of the thermally-decomposable material at a predetermined interval on the first growth blocking film; and forming a second growth blocking film on a resultant structure to enclose the pattern of the thermally-decomposable material.

The thermally-decomposable material can be thermally decomposed at a temperature where the nitride semiconductor crystal grows. The thermally-decomposable oxide comprises one selected from a group consisting of ZnO, MgO, CaO, CdO, FeO and TiO₂. Alternatively, the thermally-decomposable material comprises a thermally-decomposable resin. The thermally-decomposable resin comprises a photoresist polymer which is decomposable at a temperature of 250° C. to 600° C. The thermally-decomposable resin comprises a thermosetting resin which is decomposable at a temperature of 250° C. to 600° C. In forming the nitride semiconductor layer, the thermally-decomposable material is decomposed, leaving an empty space which serves as the flow-through pattern for flowing through an etchant.

According to further another aspect of the invention for realizing the object, there is provided a method for manufacturing a nitride semiconductor device comprising steps of:

forming a pattern of a thermally-decomposable material and a growth blocking film enclosing the pattern on a base substrate having a nitride semiconductor crystal plane in an upper surface thereof;

etching the growth blocking film between regions of the pattern to expose partial areas of the crystal plane of the base substrate;

forming a nitride semiconductor crystal layer covering the growth blocking film flow-through pattern by growing a nitride semiconductor crystal from the partial areas of the exposed crystal plane while the thermally-decomposable material is thermally decomposed to form a flow-through pattern.

According to an embodiment of the invention, the manufacturing method further comprises: after the step of forming the nitride semiconductor crystal layer,

flowing an etchant through the flow-through pattern to separate the nitride semiconductor crystal layer from the base substrate; and

sequentially forming a first conductivity type clad layer, an active layer and a second conductivity type clad layer on the nitride semiconductor crystal layer separated.

According to another embodiment of the invention, the manufacturing method further comprises:

sequentially forming a first conductivity type clad layer, an active layer and a second conductivity type clad layer on the nitride semiconductor crystal layer after the step of forming the nitride semiconductor crystal layer; and

flowing an etchant through the flow-through pattern to separate the base substrate after the step of forming the second conductivity type clad layer.

In the specification, the term ‘nitride gallium (GaN)-based semiconductor’ or ‘nitride semiconductor’ denotes a binary, ternary or quaternary compound semiconductor having a composition expressed by AlₓGa_{y}In_{(1-x-y)}N, where 0≦x≦1, 0≦y≦1, and 0≦x+y≦1.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view illustrating a semiconductor laminated structure according to an embodiment of the invention;

FIGS. 2 to 9 are cross-sectional views illustrating a method for manufacturing the semiconductor laminated structure of FIG. 1, a semiconductor nitride semiconductor crystal substrate and a nitride semiconductor device obtained therefrom; and

FIGS. 10 to 12 are cross-sectional views illustrating a method for manufacturing a nitride semiconductor device according to another embodiment of the invention.

### DETAILED DESCRIPTION OF THE PREFERRED EMBODIMENT

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and fully convey the scope of the invention to those skilled in the art. In the drawings, the shapes and dimensions may be exaggerated for clarity, and the same reference signs are used to designate the same or similar components throughout.

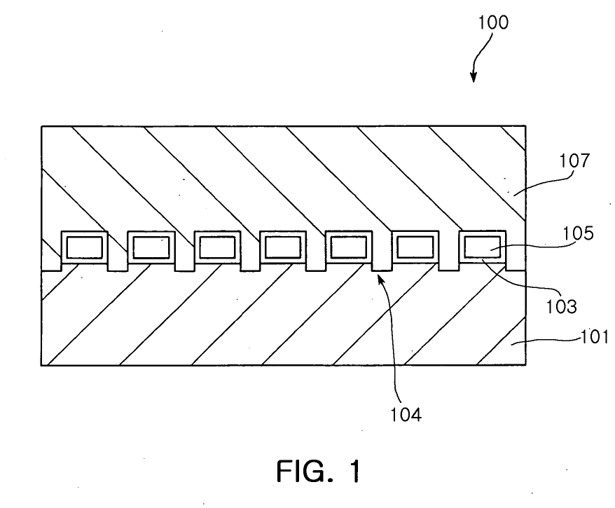

FIG. 1 is a cross-sectional view illustrating a semiconductor laminated structure according to an embodiment of the invention. Referring to FIG. 1, the semiconductor laminated structure 100 includes a base substrate 101, separators 103 and 105 and a nitride semiconductor crystal layer 107. The separators 103 and 105 include a follow-through pattern 105 extended horizontally on the base substrate 101 at a predetermined interval and a growth blocking film 103 enclosing the flow-through pattern 105. The flow-through pattern 105 serves as a path for an etchant to easily flow therethrough. The flow-through pattern 105 is at least partially empty. The etchant is flown through the flow-through pattern 105 by removing a nitride semiconductor and the growth blocking film 103 between regions of the flow-through pattern 105. This allows the semiconductor crystal layer 107 to be easily separated from the base substrate 101.

The base substrate 101 has a nitride semiconductor crystal plane in an upper surface thereof. As shown in FIG. 1, an example of the base substrate 101 includes but not limited to a single layer nitride semiconductor substrate. Alternatively, the base substrate may adopt a substrate having a nitride semiconductor crystal plane in an upper part. That is, the base substrate may utilize a multi-layer substrate having a heterogeneous substrate (e.g., a sapphire substrate) in a lower part and a nitride semiconductor layer in an upper part.

Between the regions of the flow-through pattern 105, the upper surface of the base substrate 101 is in contact with the nitride semiconductor layer 107. Also, the nitride semiconductor layer 107 covers the separators 103 and 105, extending over the growth blocking film 103. As stated later, the nitride semiconductor crystal layer 107 is grown from a contact part 104 between the base substrate 101 and the nitride semiconductor crystal layer 107. Therefore, the contact part 104 serves as a window for growing the nitride semiconductor crystal layer 107.

The semiconductor laminated structure 100 is easily applicable in producing a low-defect and high-quality nitride semiconductor crystal layer, substrate and device. That is, the nitride semiconductor crystal layer 107 is not only grown from a nitride semiconductor material (the upper surface of the base substrate 101) but also from the window and then extends laterally to fully cover the separators 103 and 105. In this fashion, crystal match with the base substrate 101a and growth by Epitaxial Lateral Overgrowth (ELOG) enable the nitride semiconductor layer 107 to exhibit low defects and high quality.

In addition, the etchant (etching gas or etching solution) is flown through the flow-through pattern 105, thereby easily removing the nitride semiconductor material and the growth blocking film 103 between the regions of the flow-through pattern 105. This allows the base substrate 101 to be removed unharmed with great reliability. The nitride semiconductor crystal layer 107 removed can be easily employed as a nitride semiconductor crystal substrate for manufacturing other device. Alternatively, a device (e.g., LED) is manufactured first on the nitride semiconductor crystal layer 107 and then the base substrate 101 is removed. In either case, the semiconductor laminated structure 100 can be beneficially used in manufacturing a high-quality nitride semiconductor crystal substrate or device.

Preferably, the growth blocking film 103 is made of an insulating material selected from a group consisting of SiO₂, SiNₓ and Al₂O₃. Alternatively, the growth blocking film 103 is made of a refractory metal such as tungsten or molybdenum.

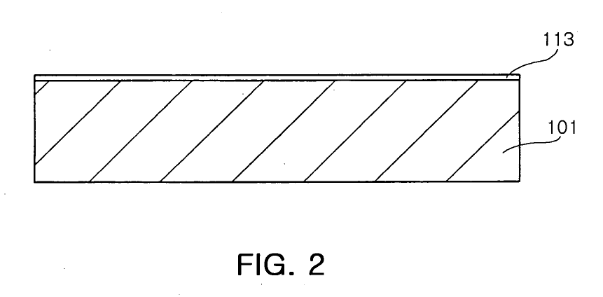

FIGS. 2 to 9 are cross-sectional views for explaining a method for manufacturing the semiconductor laminated structure of FIG. 1, a nitride semiconductor crystal substrate and a nitride semiconductor device obtained therefrom.

First, referring to FIG. 2, a first growth blocking film 113 is grown on a base substrate 101. As described above, the base substrate 101 may adopt a nitride semiconductor substrate or a heterogeneous substrate including a nitride semiconductor layer. The growth blocking film 113 is made of an insulating material such as SiO₂ or a refractory metal such as tungsten or molybdenum.

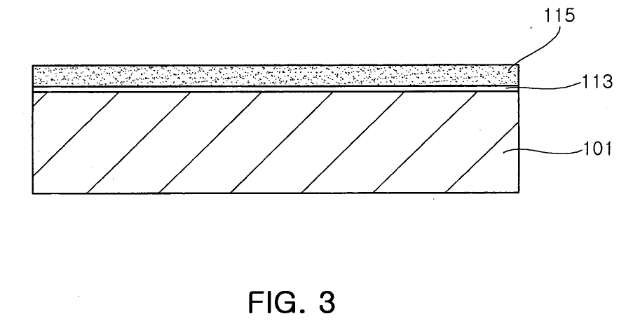

Then, as shown in FIG. 3, a thermally-decomposable material layer 115 is formed on the growth blocking film 113. The thermally-decomposable material layer is made of a material that can be easily thermally decomposed at a temperature where a nitride semiconductor crystal grows (about 800° C. or more). Preferably, the thermally-decomposable material layer 115 is made of a thermally decomposable oxide selected from a group consisting of ZnO, MgO, CaO, CdO, FeO and TiO₂. Alternatively, the thermally decomposable material layer 115 is formed of a thermally-decomposable resin. The thermally-decomposable resin is exemplified by a photoresist polymer decomposable at a temperature of 250 to 600° C. or a thermosetting resin. For example, an epoxy resin containing a brominated flame retardant, a phenolic resin or a polyurethane resin may be employed to form a thermally decomposable resin layer having a decomposition temperature of 250 to 600° C.

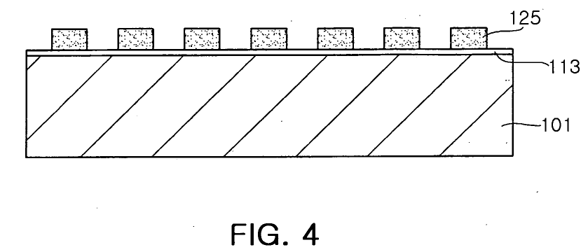

Next, as shown in FIG. 4, the thermally-decomposable material layer 115 is patterned via photoetching to form a thermally-decomposable material pattern 125. The pattern 125 may be shaped as a plurality of strips extended at a uniform interval.

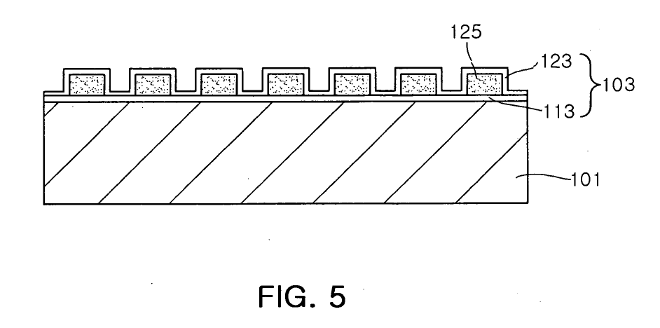

Thereafter, referring to FIG. 5, a second growth blocking film 123 is thinly disposed along the contour of the thermally decomposable material pattern 125. Thus, the thermally-decomposable material pattern 125 is enclosed by a growth blocking film 103.

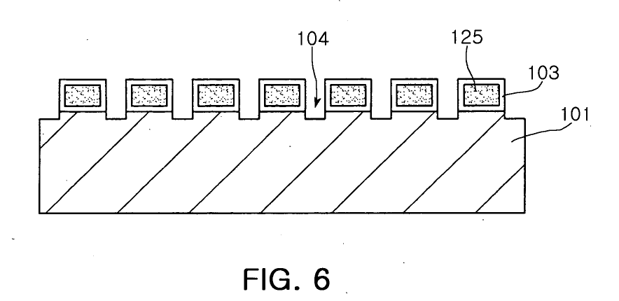

Then, referring to FIG. 6, the growth blocking film 103 between regions of the thermally-decomposable material pattern 125 is etched to expose partial areas of a nitride crystal plane of the base substrate 101. The partial areas of the nitride crystal plane exposed serve as a window 104 for a later nitride crystal growth. Here, the thermally-decomposable material pattern 125 is still enclosed by the growth blocking film 103.

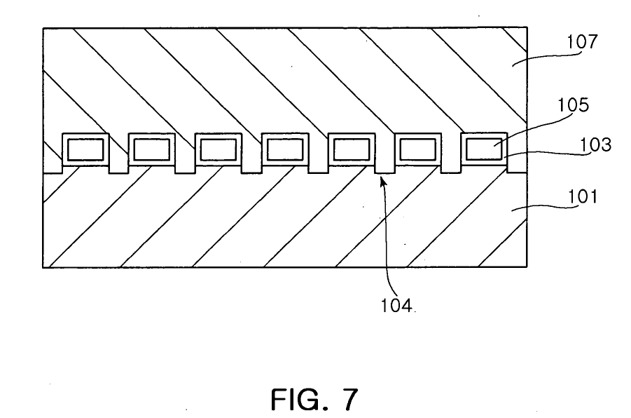

Subsequently, as shown in FIG. 7, a nitride semiconductor crystal is grown through the window 104. Here, the nitride semiconductor crystal can be grown via Metal Organic Chemical Vapor Deposition (MOCVD), Pulsed Laser Deposition (PLD), Hydride Vapor Phase Epitaxy (HVPE) or the like. In an area where the growth blocking film 103 is formed, crystal growth is restrained. Therefore, the crystal growth is initiated only in the window 104 where the partial areas of the crystal plane are exposed. Therefore, in an early stage, the nitride semiconductor crystal grows from the window 104 and then extends laterally via ELOG to fully cover the growth blocking film 103. Consequently, a nitride semiconductor crystal layer 107 is formed to a predetermined thickness on the window of the base substrate 101 and the growth blocking film 103.

The nitride semiconductor crystal grows at a high temperature of about 800° C. or more, preferably 1000° C. or more so that a thermally-decomposable material pattern 125 is thermally decomposed during the crystal growth. At this time, since the growth blocking film 103 encloses the thermally-decomposable material pattern 125, a byproduct gas generated by thermal decomposition of the thermally-decomposable material pattern 125 fails to spread to the nitride semiconductor crystal layer 107. On the contrary, the gas is exhausted through a cross-section of the thermally-decomposable material pattern 125. This prevents defects in the nitride semiconductor crystal layer 107 resulting from spread of the gas generated by the thermal decomposition.

In this fashion, during growth of the nitride semiconductor crystal layer 107, the thermally-decomposable material 125 is thermally decomposed, thereby leaving an empty area. Even after growth of the nitride semiconductor crystal layer 107, some thermally-decomposable material may remain. But the empty area caused by thermal decomposition suffices for forming a flow-through pattern 105 through which an etchant flows.

The nitride semiconductor layer 107 formed by crystal growth exhibits very high-quality crystalinity due to three reasons described below. First, the nitride semiconductor crystal layer 107 grows from the nitride semiconductor crystal plane (the window 104 of the base substrate 101). This considerably reduces defects over a conventional nitride semiconductor crystal layer grown from a heterogeneous substrate surface. Second, the nitride semiconductor crystal layer 107 is grown via ELOG. Accordingly, this lowers dislocation density in portions of the nitride semiconductor crystal layer 107 grown laterally (especially, an area just over the growth blocking film 103). Third, the growth blocking film 103 prevents the byproduct gas (gas generated by thermal decomposition of the thermally decomposable material) from spreading to the nitride semiconductor crystal layer 107. For the reasons just described, the nitride semiconductor crystal layer 107 is reduced in defects and highly improved in crystalinity.

The processes just described produce the semiconductor laminated structure 100 shown in FIG. 1 (or FIG. 7). Such a semiconductor laminated structure is employed to obtain a high-quality nitride semiconductor substrate or nitride semiconductor device.

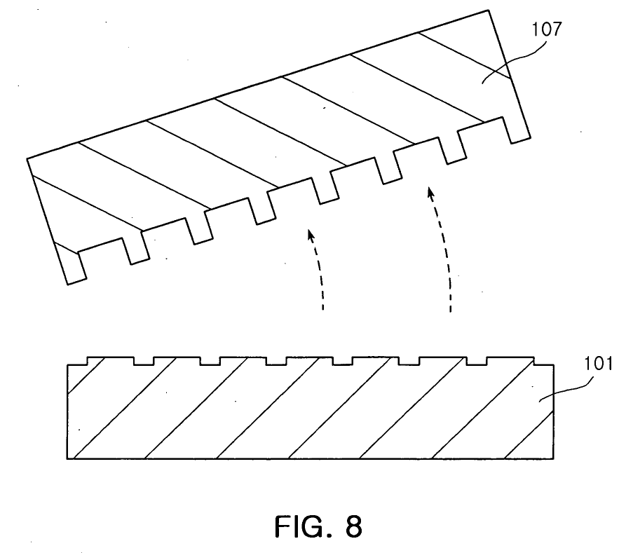

Referring to FIG. 8, the nitride semiconductor crystal layer 107 of FIG. 7 is separated. That is, at least one etchant is flown through the flow-through pattern 105 to remove the growth blocking film 103 and then the nitride semiconductor crystal in the window 104 between the regions of the flow-through pattern 105. This enables the nitride semiconductor crystal layer 107 to be easily separated from the base substrate 101 undamaged. The nitride semiconductor layer 107 separated may be used as a high-quality nitride semiconductor crystal substrate. Prior to this process, a separated surface of the semiconductor crystal layer 107 may be polished or washed.

The base substrate 101 separated is reusable. Therefore, according to the invention, one base substrate 101 is reusable or recyclable several times, thereby saving costs for materials. Prior to this process, a separated surface of the base substrate 101 may be polished or washed.

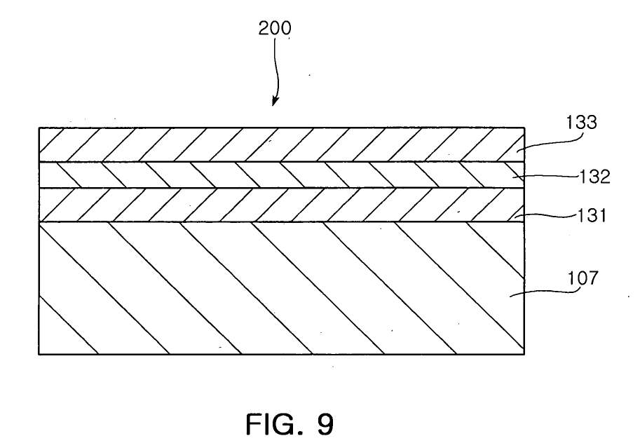

The nitride semiconductor crystal layer 107 separated as just described may be adopted for a nitride semiconductor crystal substrate to manufacture a nitride semiconductor device such as an LED, a bipolar transistor or a field effect transistor (FET). FIG. 9 illustrates an example thereof.

Referring to FIG. 9, the nitride semiconductor crystal layer 107 separated is employed as the nitride semiconductor crystal substrate to manufacture an LED device. The crystal layer 107 has an n-type clad layer 131 of an n-type GaN-based material, an active layer 132 and a p-type clad layer 133 of a p-type GaN-based material formed sequentially thereon. This allows a low-defect and high-quality LED device 200 to be formed on the high-quality crystal substrate 107. The substrate 107 is made of a low-defect and high-quality nitride semiconductor crystal so that the clad layers 131 and 133 and the active layer 132 formed thereon also exhibit high-quality crystalinity.

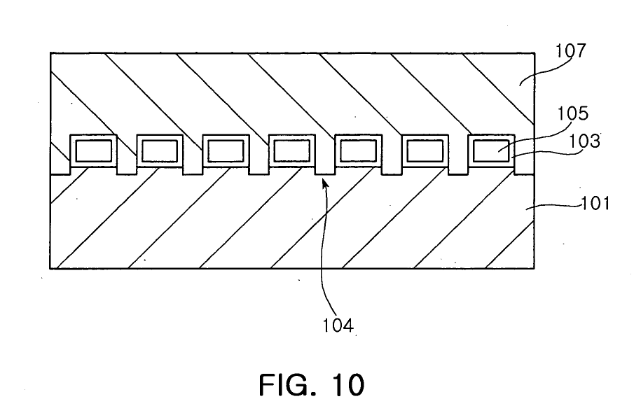

FIGS. 10 to 12 are cross-sectional views for explaining a method for manufacturing a nitride semiconductor device (especially LED device) according to another embodiment of the invention. This embodiment is identical to the aforesaid embodiment except that the clad layers and active layer are first formed on the nitride semiconductor crystal layer 107 and then the base substrate 101 is separated.

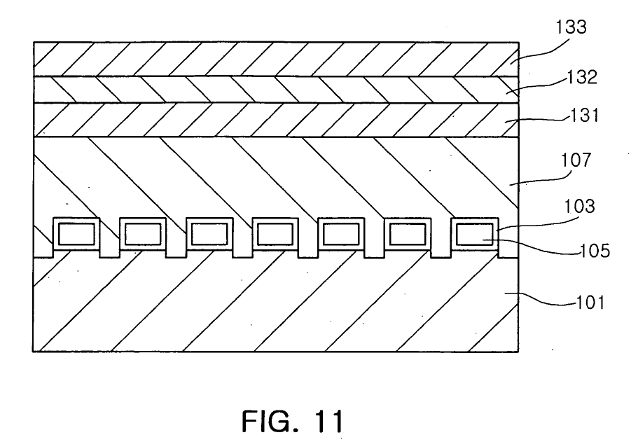

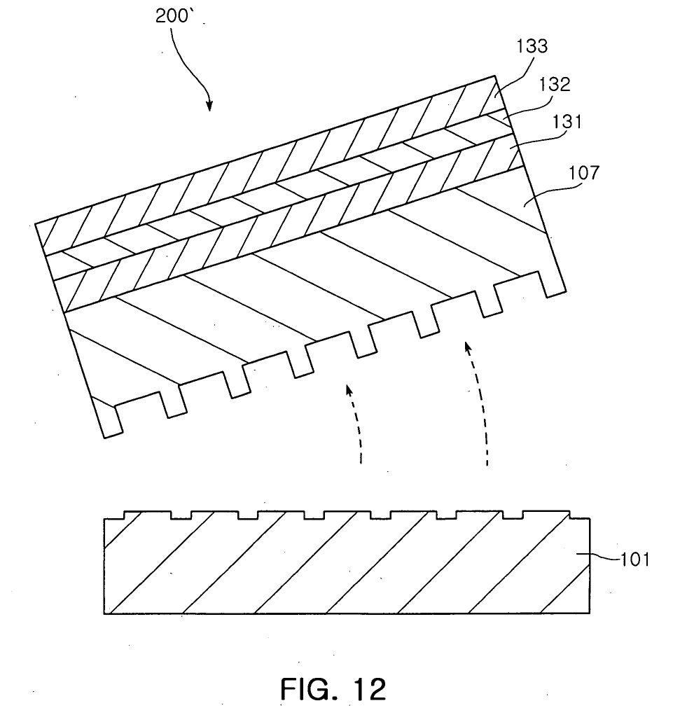

As shown in FIG. 10, a semiconductor laminated structure having the nitride semiconductor crystal layer 107 is obtained via the processes explained with reference to FIGS. 2 to 7. Next, as shown in FIG. 11, the nitride semiconductor crystal layer 107 has an n-type GaN-based clad layer 131, an active layer 132, a p-type GaN-based clad layer 133 formed sequentially thereon. Accordingly, an LED device part is formed on the base substrate 101. Thereafter, as shown in FIG. 12, an etchant is flown through the flow-through pattern 105 to separate the base substrate 101 from the LED device part including the nitride semiconductor crystal layer 107. This produces a high-quality nitride semiconductor device (LED device 200 according to this embodiment).

As set forth above, according to preferred embodiments of the invention, a semiconductor laminated structure includes a flow-through pattern enclosed by a growth blocking film and a window for crystal growth. The semiconductor laminated structure is employed to obtain a low-defect and high-quality nitride semiconductor crystal layer or substrate. The nitride semiconductor crystal layer or substrate easily produces a high-quality nitride semiconductor device such as an LED device.

While the present invention has been shown and described in connection with the preferred embodiments, it will be apparent to those skilled in the art that modifications and variations can be made without departing from the spirit and scope of the invention as defined by the appended claims.

What is claimed is:

1. A semiconductor laminated structure comprising:
a base substrate having a nitride semiconductor crystal plane in an upper surface thereof;
a growth blocking film enclosing a flow-through pattern which is extended horizontally on the base substrate at a predetermined interval; and
a nitride semiconductor crystal layer formed on the base substrate to contact the upper surface thereof between regions of the flow-through pattern, the nitride semiconductor crystal layer covering the growth blocking film.

2. The semiconductor laminated structure according to claim 1, wherein the base substrate is a nitride semiconductor substrate.

3. The semiconductor laminated structure according to claim 1, wherein the base substrate comprises a heterogeneous substrate in a lower part and a nitride semiconductor layer in an upper part.

4. The semiconductor laminated structure according to claim 1, wherein the growth blocking film comprises one selected from a group consisting of SiO₂, SiNₓ and Al₂O₃.

5. The semiconductor laminated structure according to claim 1, wherein the growth blocking film comprises a refractory metal.

6. A method for manufacturing a nitride semiconductor crystal substrate comprising steps of:
forming a pattern of a thermally-decomposable material and a growth blocking film enclosing the pattern on a base substrate having a nitride semiconductor crystal plane in an upper surface thereof;
etching the growth blocking film between regions of the pattern to expose partial areas of the crystal plane of the base substrate;
forming a nitride semiconductor crystal layer covering the growth blocking film by growing a nitride semiconductor crystal from the partial areas of the exposed crystal plane while the thermally-decomposable material is thermally decomposed to form a flow-through pattern; and
flowing an etchant through the flow-through pattern to separate the nitride semiconductor crystal layer from the base substrate.

7. The method according to claim 6, wherein the step of forming the pattern of the thermally-decomposable material and the growth blocking film comprises:
forming a first growth blocking film on the base substrate;
forming the pattern of the thermally-decomposable material at a predetermined interval on the first growth blocking film; and
forming a second growth blocking film on a resultant structure to enclose the pattern of the thermally-decomposable material.

8. The method according to claim 6, wherein the thermally-decomposable material comprises a thermally-decomposable oxide.

9. The method according to claim 8, wherein the thermally-decomposable oxide comprises one selected from a group consisting of ZnO, MgO, CaO, CdO, FeO and TiO₂.

10. The method according to claim 6, wherein the thermally-decomposable material comprises a thermally-decomposable resin.

11. The method according to claim 10, wherein the thermally-decomposable resin comprises a photoresist polymer which is decomposable at a temperature of 250° C. to 600° C.

12. The method according to claim 10, wherein the thermally-decomposable resin comprises a thermosetting resin which is decomposable at a temperature of 250° C. to 600° C.

13. The method according to claim 6, wherein the growth blocking growth film comprises one selected from a group consisting of SiO₂, SiNₓ and Al₂O₃.

14. The method according to claim 6, wherein the growth blocking growth film comprises a refractory metal.

15. A method for manufacturing a nitride semiconductor device comprising steps of:
forming a pattern of a thermally-decomposable material and a growth blocking film enclosing the pattern on a base substrate having a nitride semiconductor crystal plane in an upper surface thereof;
etching the growth blocking film between regions of the pattern to expose partial areas of the crystal plane of the base substrate;
forming a nitride semiconductor crystal layer covering the growth blocking film by growing a nitride semiconductor crystal from the partial areas of the exposed crystal plane while the thermally-decomposable material is thermally decomposed to form a flow-through pattern.

16. The method according to claim 15, wherein the step of forming the pattern and the growth blocking film comprises:
forming a first growth blocking film on the base substrate;
forming the pattern of the thermally decomposable material at a predetermined interval on the first growth blocking film; and
forming a second growth blocking film on a resultant structure to enclose the pattern of the thermally-decomposable material.

17. The method according to claim 15, further comprising: after the step of forming the nitride semiconductor crystal layer,
flowing an etchant through the flow-through pattern to separate the nitride semiconductor crystal layer from the base substrate; and
sequentially forming a first conductivity type clad layer, an active layer and a second conductivity type clad layer on the separated nitride semiconductor crystal layer.

18. The method according to claim 15, further comprising:
sequentially forming a first conductivity type clad layer, an active layer and a second conductivity type clad layer on the nitride semiconductor crystal layer after the step of forming the nitride semiconductor crystal layer; and
flowing an etchant through the flow-through pattern to separate the base substrate after the step of forming the second conductivity type clad layer.

19. The method according to claim 15, wherein the thermally-decomposable material comprises a thermally-decomposable oxide.

20. The method according to claim 19, wherein the thermally-decomposable oxide comprises one selected from a group consisting of ZnO, MgO, CaO, CdO, FeO and TiO₂.

21. The method according to claim 15, wherein the thermally-decomposable material comprises a thermally-decomposable resin.

22. The method according to claim 21, wherein the thermally-decomposable resin comprises a photoresist polymer which is decomposable at a temperature of 250° C. to 600° C.

23. The method according to claim 21, wherein the thermally-decomposable resin comprises a thermosetting resin which is decomposable at a temperature of 250° C. to 600° C.

24. The method according to claim 15, wherein the growth blocking film comprises one selected from a group consisting of SiO₂, SiNₓ and Al₂O₃.

25. The method according to claim 15, wherein the growth blocking film comprises a refractory metal.
